(19) United States
(12) Patent Application Publication
(10) Pub. No.: US 2006/0195732 A1
(43) Pub. Date: Aug. 31, 2006

(54) Method and system for executing test cases for a device under verification

(76) Inventors: Joerg Deutschle, Winnenden (DE); Harald Gerst, Boeblingen (DE); Joerg Walter, Tuebingen (DE)

Correspondence Address: IBM CORPORATION;INTELLECTUAL PROPERTY LAW, 11400 BURNET ROAD, AUSTIN, TX, 78758, US

(21) Appl. No.: 11/055,839

(22) Filed: Feb. 11, 2005

(51) Int. Cl. G01R 31/28

(52) U.S. Cl. 714/724

(57) ABSTRACT

The present invention relates to a method and system for executing test cases for a device by mapping sequences of instructions and/or operation into a data flow graph, which data flow graph includes a plurality of nodes (20) and a plurality of arcs (22) connecting the nodes (20). The method comprises a step of mapping at least one instruction or operation into the corresponding node (20) of the data flow graph, a further step of mapping sequential dependencies of said instruction and/or operation into the corresponding arcs (22) between the nodes (20), and another step of mapping parallel streams of the instructions and/or operations into the corresponding arcs (22), wherein each arc (22) originates from a single node (20) and ends in a single node (20). There are randomly generated as well as deterministic sequences of instructions and/or operations mapped into the data flow graph.

### BACKGROUND OF THE INVENTION

1. Field of the Invention

The present invention relates to a method and system for executing test cases for a device under verification. In particular, the invention relates to a method and system for executing sequences of instructions and/or operations for the device under verification.

2. Description of the Related Art

The test case is a sequence of instructions, commands and/or operations applied to the device under verification. In particular, the test case may be a predetermined set of inputs and a description of the expected responses for the device under verification.

A conventional method for testing a device, e.g. a hardware device, may be realized by a directed random simulation. For that purpose streams of random instructions and/or commands are applied to the device under verification. Since a complete random selection of the instructions and commands is not desired, the randomness is restricted by control parameters, resulting to said directed random simulation.

However, it is very difficult, if possible, to force a sequence of random instructions and/or commands. The hard coding sequences in a random command driver would weaken the concept of a random verification. A reduction of the randomness and an increase of deterministic execution require a lot of parameters and parameter configurations, which is not desired. On the other hand, deterministic sequences are often required, if the test case generator does not create certain scenarios or if the probability of said scenarios is insufficient. In many cases such a sequence of instructions and/or commands is required by the device under verification in order to check the function of the device sufficiently.

This often leads to the development of methods using two different environments. A first environment is provided for deterministic test cases without any random timings and events. A second environment is provided for test cases with random instructions and/or commands without any sequences of deterministic instructions and/or commands.

Further methods for executing test cases are known, wherein the control of the test cases is mostly random, but some of the test cases are deterministic.

### OBJECT OF THE INVENTION

It is an object of the present invention to provide a method for executing test cases for a device under verification, which overcomes the above disadvantages.

### SUMMARY OF THE INVENTION

The above object is achieved by a method as laid out in the independent claims. Further advantageous embodiments of the present invention are described in the dependent claims and are taught in the description below.

The core idea of the invention is a generic mechanism to map randomly generated as well as deterministic test cases into data flow graphs. The data flow graphs include a plurality of nodes and a plurality of arcs connecting the nodes. The test cases, i.e. the sequences of the instructions and/or operations are mapped into the data flow graph. The data flow graph may be changed and/or extended dynamically. Several data flow graphs may exist in parallel. In particular, the data flow graphs may be created by different generators. This allows a parallel execution of random and deterministic test cases.

Each node in the data flow graph represents an instruction or an operation for the device under verification. The transitions between the nodes of the data flow graph describe the structure of the test case. Software drivers in the verification environment stimulate the inputs of the device under verification with the information stored in the active nodes of the data flow graphs.

An arbitrary number of data flow graphs may be active in parallel. The data flow graph may be generated at the simulation startup time, e.g. by a parsing module reading a deterministic test case. Further sequences of instructions and/or operations may be stimulated or irritated by random events, e.g. interrupts or exceptions. This results in different timing and execution conditions for the same sequence on every time.

A further advantage of the present invention is the improved verification capabilities, since the environment coding and maintenance effort is reduced, because only one environment is necessary.

Further advantageous embodiments of the present invention are described in the dependent claims and are taught in the description below.

### BRIEF DESCRIPTION OF THE DRAWINGS

The above as well as additional objectives, features and advantages of the present invention will be apparent in the following detailed written description.

The novel and inventive features believed characteristic of the invention are set forth in the appended claims. The invention itself, their preferred embodiments and advantages thereof will be best understood by reference to the following detailed description of preferred embodiments in conjunction with the accompanied drawings, wherein:

FIG. 1 shows a diagram of a verification environment for the method according to the present invention.

### DETAILED DESCRIPTION OF THE INVENTION

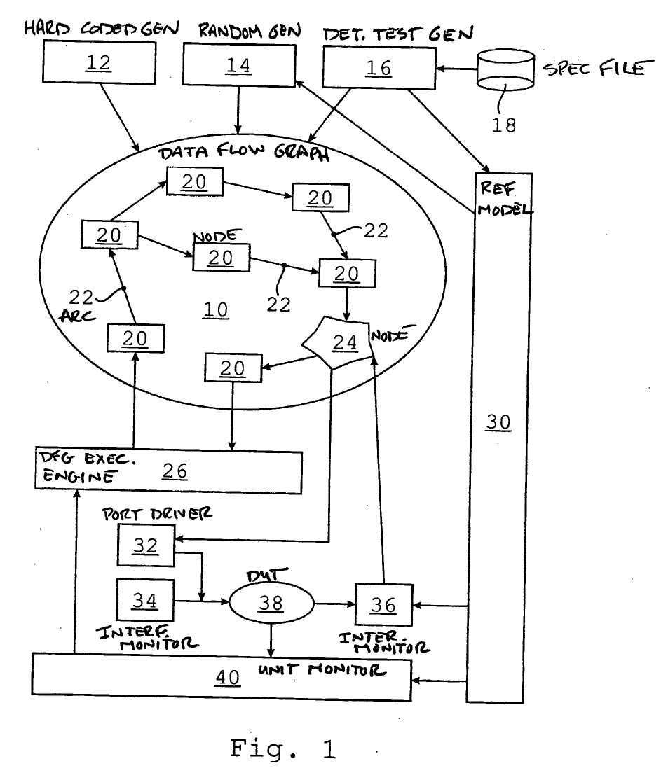

FIG. 1 shows a schematic diagram of a verification environment, which may use the method according to the present invention. In this example the verification environment is provided for an address translator.

The verification environment comprises a data flow graph (DFG) 10. Additionally the verification environment may comprise further parallel data flow graphs 10, which are not represented in FIG. 1. The data flow graph 10 includes a plurality of nodes 20 and a plurality of arcs 22 connecting the nodes 20. The arcs 22 are unidirectional. In this example the nodes 20 and the arcs 22 form substantially a loop, which is connected with a DFG execution engine 26. The nodes 20, the arcs 22 and the DFG execution engine 26 form a closed token ring. However, it is not necessary, that the data flow graph 10 forms a loop. The connection between the data flow graph 10 and the DFG execution engine 26 basically works in such a way, that the DFG execution engine 26 is able to call all nodes 20, which are in an active state. The DFG execution engine 26 may handle token passing between the nodes 20, in order to determine, which nodes 20 are in an active state. The DFG execution engine 26 makes a note, or log of the active nodes 20 and is able to call them. Thus the DFG execution engine 26 has a connection to all nodes 20.

Every node 20 of the data flow graph 10 may be connected with port drivers and/or interface monitors. For example, in FIG. 1 the node 24 is connected with the port driver 32 and the interface monitor 36 for output events. An example with two nodes 20 includes the following steps: A first node 20 sends a request to the device to be tested by transferring a corresponding data package to the port driver 32. At this time the first node 20 is active. After that, the first node 20 is deactivated and a token is sent to a second node 20 via the DFG execution engine 26. Then, the second node 20 is activated. The second node 20 checks the response of the device via the interface monitor 36 for output events, e.g. if the response is correct. After that, the second node 20 terminates the procedure.

Further the verification environment comprises three generators, namely a hard coded generator 12, a random generator 14 and a deterministic test case generator 16. The hard coded generator 12, the random generator 14 and the deterministic test case generator 16 feed the data flow graph 10 and the DFG execution engine 26. The hard coded generator 12 creates fixed sequences required for DUV (design under verification) operations, e.g. a firmware load sequence. Such a fixed sequence DFG is usually activated upon certain events in the DUV, e.g. reset or recovery operations.

The random generator 14 creates random data flow graphs 10 during the runtime of the simulation. The deterministic test case generator 16 creates deterministic data flow graphs 10 at the startup time of the simulation. A specification file 18 feeds the deterministic test case generator 16.

Additionally the environment provides means for creating manually the data flow chart 10.

The verification environment comprises further a reference model 30, an interface monitor 34 for input events, a design under test (DUT) 38 and a unit monitor 40. The reference model 30 receives information from the deterministic test case generator 16 and sends information to the interface monitor 36 for output events and to the unit monitor 40. The DUT 38 is connected between the port driver 32, the interface monitor 34 for input events and the interface monitor 36 for output events and provides the unit monitor 40 with information.

Within the data flow graph 10 one or more data flow graphs may be specified. The data flow graphs include a plurality of nodes 20 and a plurality of arcs 22 connecting the nodes 20. The test cases are mapped as sequences of the instructions and/or operations into the data flow graph 10. The data flow graph 10 may be changed and/or extended dynamically.

The environment may have several data flow graphs 10. The different generators 12, 14 and/or 16 may feed the different data flow graph 10 in order to execute different test cases. This allows a parallel execution of random and deterministic test cases.

Each node 20 in the data flow graph represents an instruction or an operation for the device under verification. The arcs 22 between the nodes 20 of the data flow graph describe the structure of the test case. The inputs of the device are stimulated by software generators 12, 14 and/or 16 within the verification environment. The information stored in the active nodes 20 of the data flow graphs is used.

An arbitrary number of data flow graphs may be active in parallel within the verification environment. The data flow graph may be generated at the simulation startup time by the deterministic test case generator 16. Further sequences of instructions and/or operations may be stimulated by random events, e.g. interrupts or exceptions. This allows different timing and execution conditions for the same sequence on every time.

The main data flow propagates through the DFG execution engine 26. The active nodes 20 are determined by the DFG execution engine 26 via tokens, which propagates through the data flow graph. Whenever a node 20 is complete it passes on a token to the next nodes 20.

The data flow graph 10 and the DFG execution engine 26 are generic and independent of the device. On the other hand, the generators 12, 14 and 16 of the test cases and the port driver 32 depend on the device under verification.

The present invention can also be embedded in a computer program product, which comprises all the features enabling the implementation of the methods described herein. Further, when loaded in computer system, said computer program product is able to carry out these methods.

Although illustrative embodiments of the present invention have been described herein with reference to the accompanying drawings, it is to be understood that the present invention is not limited to those precise embodiments, and that various other changes and modifications may be affected therein by one skilled in the art without departing from the scope or spirit of the invention. All such changes and modifications are intended to be included within the scope of the invention as defined by the appended claims.

### List of Reference Numerals

10 data flow graph

12 hard coded generator

14 random generator

16 deterministic test case generator

18 specification file

20 node

22 arc

24 node

26 DFG execution engine

30 reference model

32 port driver

34 interface monitor for input events

36 interface monitor for output events

38 design under test

40 unit monitor

1. A method for executing test cases for a device by mapping sequences of instructions and/or operations into a data flow graph, which data flow graph includes a plurality of nodes (20) and a plurality of arcs (22) connecting the nodes (20), and which method comprises the steps of:
mapping at least one instruction or operation into the corresponding node (20) of the data flow graph;
mapping at least one sequential dependency of said instruction and/or operation into the corresponding arcs (22) between the nodes (20); and
mapping parallel streams of the instructions and/or operations into the corresponding arcs (22), wherein each arc (22) originates from a single node (20) and ends in a single node (20); and
wherein randomly generated and deterministic sequences of instructions and/or operations are mapped into the data flow graph.

2. The method according to claim 1, wherein a dynamic modification of the data flow graph is provided during runtime by inserting at least one node (20) and/or at least one arc (22) to the existing data flow graph and/or by deleting at least one node (20) and/or at least one arc (22) from the existing graph.

3. The method according to claim 2, wherein the instruction or operation represented by a node (20) is activated by receiving a token.

4. The method according to claim 3, wherein the instruction or operation represented by a node (20) may be finished instantaneously or may take a plurality of simulation cycles.

5. The method according to claim 4, wherein the execution of the data flow graph requires, that all actions related to the node (20) are complete.

6. The method according to claim 5, wherein the activation of successive nodes (20) takes place by sending out a token on every arc (22) originating from the node (20).

7. The method according to claim 6, wherein an arbitrary number of nodes (20) is active at any given time.

8. The method according to claim 6, wherein an arbitrary number of data flow graphs is active at any given time, using additional means for parallel execution.

9. The method according to claim 6, wherein a start up criteria is provided in order to activate the data flow graph, thereby providing means to trigger the execution of a data flow graph depending on an external event.

10. The method according to claim 9, wherein the execution of the following node (20) is delayed by a predetermined number of simulation cycles.

11. The method according to claim 10, wherein an existing deterministic test case may be repeated by an activation of a random generator.

12. The method according to claim 11, wherein at least one deterministic data flow graph is mixed with at least one random instruction and/or operation generated during runtime.

13. The method according to claim 12, wherein at least one data flow graph is connected with at least another data flow graph.

14. The method according to claim 13, wherein a predetermined relationship between random and deterministic test cases is specified.

15. A system that executes test cases for a device by mapping sequences of instructions and/or operations into a data flow graph, which data flow graph includes a plurality of nodes (20) and a plurality of arcs (22) connecting the nodes (20), said system comprising:
first means for mapping at least one instruction or operation into the corresponding node (20) of the data flow graph;
second means for mapping at least one sequential dependency of said instruction and/or operation into the corresponding arcs (22) between the nodes (20); and
third means for mapping parallel streams of the instructions and/or operations into the corresponding arcs (22), wherein each arc (22) originates from a single node (20) and ends in a single node (20); and
wherein randomly generated and deterministic sequences of instructions and/or operations are mapped into the data flow graph.

16. The system according to claim 15, wherein the system comprises different generators (12, 14, 16) for generating the test cases.

17. The system according to claim 16, wherein the system comprises:
at least one random generator (14) for generating randomly created test cases; and
at least one deterministic test case generator (16) for generating deterministic test cases.

18. The system according to claims 17, wherein the system is realized in hardware, software or a combination of hardware and software.

19. A computer program product stored on a computer usable medium, comprising computer readable program instruction means for executing test cases for a device by mapping sequences of instructions and/or operations into a data flow graph, which data flow graph includes a plurality of nodes (20) and a plurality of arcs (22) connecting the nodes (20), said system comprising:
first instruction means for mapping at least one instruction or operation into the corresponding node (20) of the data flow graph;
second instruction means for mapping at least one sequential dependency of said instruction and/or operation into the corresponding arcs (22) between the nodes (20); and
third instruction means for mapping parallel streams of the instructions and/or operations into the corresponding arcs (22), wherein each arc (22) originates from a single node (20) and ends in a single node (20); and
wherein randomly generated and deterministic sequences of instructions and/or operations are mapped into the data flow graph.
